(19) United States
(12) Patent Application Publication
(10) Pub. No.: US 2024/0290817 A1
(43) Pub. Date: Aug. 29, 2024

(54) IMAGE SENSOR AND METHOD OF MANUFACTURING SAME

(71) Applicant: DB HiTek Co., Ltd., Bucheon-si (KR)

(72) Inventor: Woo Sung CHOI, Cheongju-si (KR)

(21) Appl. No.: 18/315,587

(22) Filed: May 11, 2023

(30) Foreign Application Priority Data
Feb. 28, 2023 (KR) 10-2023-0026468

(51) Int. Cl. H01L 27/146

(52) U.S. Cl. CPC H01L 27/14685; H01L 27/14621; H01L 27/14627; H01L 27/14636

(57) ABSTRACT

Disclosed are an image sensor and a method of manufacturing the same. More particularly, an image sensor and a method of manufacturing the same including a passivation layer on or at a boundary, but not in a light guide, and a separate liner is in the light guide, to control the light receiving efficiency of the image sensor according to the thickness of the liner.

### CROSS REFERENCE TO RELATED APPLICATION

The present application claims priority to Korean Patent Application No. 10-2023-0026468, filed Feb. 28, 2023, the entire contents of which are incorporated herein for all purposes by this reference.

### BACKGROUND OF THE INVENTION

### Field of the Invention

The present disclosure relates generally to an image sensor and a method of manufacturing the same. More particularly, the present disclosure relates to an image sensor and a method of manufacturing the same, including a passivation layer on a boundary (e.g., between pixels), but not in a light guide, and a separate liner in the light guide to control the light receiving efficiency of the image sensor according to the thickness of the liner.

### Description of the Related Art

An image sensor is a component of an image-capturing device that generates an image in a mobile phone camera or the like. Image sensors can be classified as charge coupled device (CCD) image sensors and complementary metal oxide semiconductor (CMOS) image sensors, depending on the manufacturing processes and applications. The CMOS image sensor has been widely used due to its manufacturability (e.g., by general semiconductor chip manufacturing processing), its excellent integration competitiveness, its economic feasibility, and the ease of its connectability with peripheral chips.

FIG. 1 is a cross-sectional view illustrating a conventional image sensor 9.

Hereinbelow, a schematic structure of the conventional image sensor 9 and its problems will be described.

Referring to FIG. 1, in the conventional image sensor 9, a continuous passivation layer 910 is formed as a liner in a light guide 930 and a boundary between adjacent light guides 930. As such, the passivation layer 910 is both in a unit pixel and at the boundary between adjacent unit pixels. In addition, an insulating layer 950 is on the passivation layer 910 and in the light guide 930, a color filter 970 is on the insulating layer 950, and a microlens 990 is on the color filter 970. Thus, incident light may pass through the microlens 990 and the color filter 970 and be transferred to a light receiving element PD through the light guide 930.

In general, since the thickness of the passivation layer 910 is preset, it cannot be changed in order to stabilize device characteristics or secure reliability. For example, when the thickness of the passivation layer 910 is 1500 Å to 3000 Å, it is not easy to change the thickness of the passivation layer 910 to one outside this range. Therefore, it is also not easy to control the efficiency of the image sensor 9 for receiving incident light according to or as a function of the thickness of the passivation layer 910.

To overcome the above problem, the present inventors have conceived a novel backside illuminated image sensor having an improved structure enabling improvement in light sensitivity in the near-infrared range, which will be described in detail later.

The foregoing is intended merely to aid in the understanding of the background of the present disclosure, and is not intended to mean that the present disclosure falls within the purview of the related art or information that is already known to those skilled in the art.

### DOCUMENTS OF RELATED ART

Korean Patent No. 10-0660549, entitled “Image sensor and method of manufacturing the same.”

### SUMMARY OF THE INVENTION

Accordingly, the present disclosure has been made keeping in mind the above problems occurring in the related art, and an objective of the present disclosure is to provide an image sensor and a method of manufacturing the same, including a liner (rather than a passivation layer) in a light guide to control the light receiving efficiency according to the thickness of the liner.

Another objective of the present disclosure is to provide an image sensor and a method of manufacturing the same, in which a liner can have various thicknesses in a cavity of the light guide (e.g., after etching a passivation layer and/or forming the light guide) to control the light receiving efficiency of a light receiving element (e.g., of the image sensor).

Another objective of the present disclosure is to provide an image sensor and a method of manufacturing the same, including a liner in a pixel (e.g., of the image sensor) and in a surrounding region (e.g., a region of the image sensor surrounding the pixel[s]), to promote process convenience.

In order to achieve the above objectives, according to one aspect of the present disclosure, there is provided an image sensor including a substrate having a plurality of light receiving elements therein; a gate region on the substrate; a lower insulating layer covering the gate region; a wiring region on the lower insulating layer, the wiring region including a multi-layered metal wiring structure and an interlayer insulating layer (e.g., a multi-layered insulating layer covering the multi-layered metal wiring structure); a light guide comprising a cavity in the interlayer insulating layer above each of the light receiving elements; a boundary between adjacent light guides in or over the wiring region; an upper insulating layer on or at the boundary; a passivation layer on the upper insulating layer; and a liner in the light guide and the passivation layer.

According to another aspect of the present disclosure, the liner may be in direct contact with the interlayer insulating layer in the light guide.

According to another aspect of the present disclosure, the liner may cover sidewalls of the upper insulating layer and the passivation layer on or near the boundary.

According to another aspect of the present disclosure, the passivation layer may be spaced apart from an adjacent passivation layer on or at an adjacent boundary.

According to another aspect of the present disclosure, the image sensor may further include an insulating layer on the liner; a color filter on the insulating layer; and a lens on the color filter.

According to another aspect of the present disclosure, the liner may have a higher refractive index than the insulating layer.

According to another aspect of the present disclosure, the liner may have a higher refractive index than the passivation layer.

According to another aspect of the present disclosure, there is provided an image sensor including a substrate having a plurality of light receiving elements therein, each of the light receiving elements being in a corresponding pixel; a lower insulating layer on the substrate; a wiring region on the lower insulating layer, the wiring region including a multi-layered wiring structure and an interlayer insulating layer (e.g., a multi-layered insulating layer covering the metal wiring layer); a light guide comprising a cavity in the interlayer insulating layer above each of the light receiving elements; a boundary between adjacent light guides in adjacent pixels; a pad on the interlayer insulating layer in a surrounding region; an upper insulating layer on or at the boundary and sidewalls of the pad in the surrounding region; a passivation layer on the upper insulating layer; a liner on the passivation layer and in contact with the interlayer insulating layer or the lower insulating layer in the light guide, and an opening on or over the pad.

According to another aspect of the present disclosure, the liner may have a thickness in a range of 50 Å to 3000 Å.

According to another aspect of the present disclosure, the light guide may decrease in width as a function of depth into the cavity.

According to another aspect of the present disclosure, the liner may be on the passivation layer in the pixel and the surrounding region.

According to another aspect of the present disclosure, there is provided a method of manufacturing an image sensor, the method including forming a light receiving element in a substrate; forming a gate region on the substrate; forming a lower insulating layer covering the gate region; repeatedly forming a metal wiring layer and an interlayer insulating layer on the lower insulating layer; sequentially forming an insulating layer and a nitride layer on an uppermost interlayer insulating layer; forming an upper insulating layer, a passivation layer, and a light guide by etching the insulating layer, the nitride layer, and the interlayer insulating layer between adjacent boundaries of a unit pixel; forming a liner in the light guide and on the passivation layer on or at the boundary; and forming an insulating layer on the liner and filling the cavity.

According to another aspect of the present disclosure, the liner may be in direct contact with the lower insulating layer or the interlayer insulating layer in the light guide.

According to another aspect of the present disclosure, the upper insulating layer, the passivation layer, and the liner may be sequentially stacked on or at the boundary.

According to another aspect of the present disclosure, the passivation layer may have a higher refractive index than the upper insulating layer.

According to another aspect of the present disclosure, there is provided a method of manufacturing an image sensor, the method including forming a light receiving element in a substrate in a pixel; forming a lower insulating layer on the substrate; repeatedly forming a metal wiring layer and an interlayer insulating layer on the lower insulating layer in the pixel and a surrounding region; forming a pad on an uppermost interlayer insulating layer in the surrounding region; sequentially forming an insulating layer and a nitride layer on an uppermost interlayer insulating layer in the pixel and the surrounding region covering the pad; forming a light guide by etching the insulating layer, the nitride layer, and the interlayer insulating layer in the pixel; forming a liner in the light guide in the pixel and the surrounding region to cover the insulating layer and the nitride layer; and forming an opening by sequentially etching the liner, the nitride layer, and the insulating layer on the pad.

According to another aspect of the present disclosure, the liner may be in contact with the lower insulating layer.

The present disclosure has the following effects by the above configuration.

According to the present disclosure, by forming the liner rather than the passivation layer in the light guide, the light receiving efficiency (e.g., of the image sensor) can be easily controlled according to the thickness of the liner.

In detail, by depositing the liner, which may have a controllable and reproducible thickness, in the cavity of the light guide after etching the passivation layer, the light receiving efficiency of the light receiving element can be controlled.

In addition, by forming the liner not only in the pixel but also in the surrounding region, process convenience can be promoted.

The effects of the present disclosure are not limited to the above-mentioned effects, and other effects that are not mentioned can be clearly understood by those skilled in the art from the following description.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a cross-sectional view illustrating a conventional image sensor;

FIG. 2 is a plan view illustrating an image sensor according to an embodiment of the present disclosure;

FIG. 3 is a cross-sectional view illustrating an image sensor according to one or more embodiments of the present disclosure; and

FIGS. 4 to 11 are cross-sectional views illustrating structures made during a method of manufacturing an image sensor according to one or more embodiments of the present disclosure.

### DETAILED DESCRIPTION OF THE INVENTION

Hereinafter, exemplary embodiments of the present disclosure will be described in more detail with reference to the accompanying drawings. The embodiments of the present disclosure can be modified in various forms. Therefore, the scope of the present disclosure should not be construed as being limited to the following embodiments, but should be construed on the basis of the descriptions in the appended claims. The embodiments in the present disclosure are provided for completeness of the present disclosure and to fully convey the scope of the present disclosure to those skilled in the art.

As used herein, when an element (or layer) is referred to as being on another element (or layer), it can be directly on the other element, or one or more intervening elements (or layers) may be therebetween. In contrast, when an element is referred to as being directly on or above another component, no intervening elements are therebetween. Further, the terms “on”, “above”, “below”, “upper”, “lower”, “one side”, “side surface”, etc. are used to describe one element's relationship to one or more other elements illustrated in the drawings.

While the terms “first”, “second”, etc. may be used herein to describe various items such as various elements, regions and/or parts, these items should not be limited by these terms.

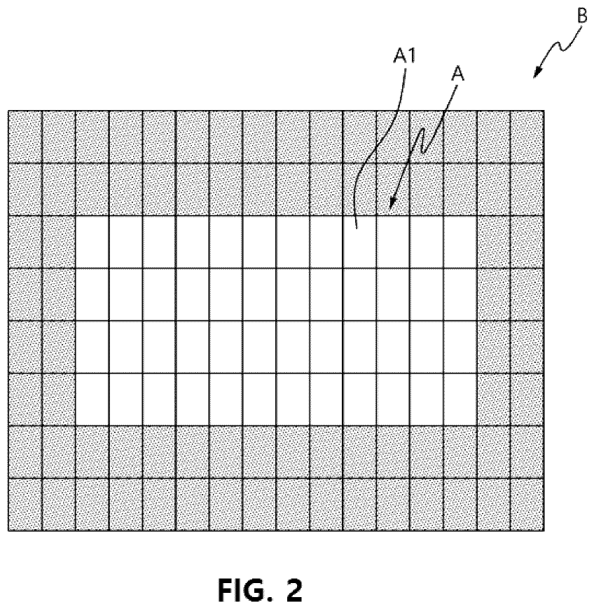

When a certain embodiment may be implemented differently, a specific process order may be performed differently from the described order. For example, two consecutively described processes may be performed substantially at the same time or performed in an order opposite to the described order. FIG. 2 is a plan view illustrating an image sensor 1 according to an embodiment of the present disclosure.

Referring to FIG. 2, the image sensor 1 according to the present disclosure includes a pixel region A. The pixel region A is a region that absorbs light from the outside and may include a plurality of unit pixels A1. A surrounding region B is a region that surrounds the pixel region A, and may be, for example, a region including processing circuitry, such as a correlated double sampler, an analog-to-digital converter, a latch, and the like.

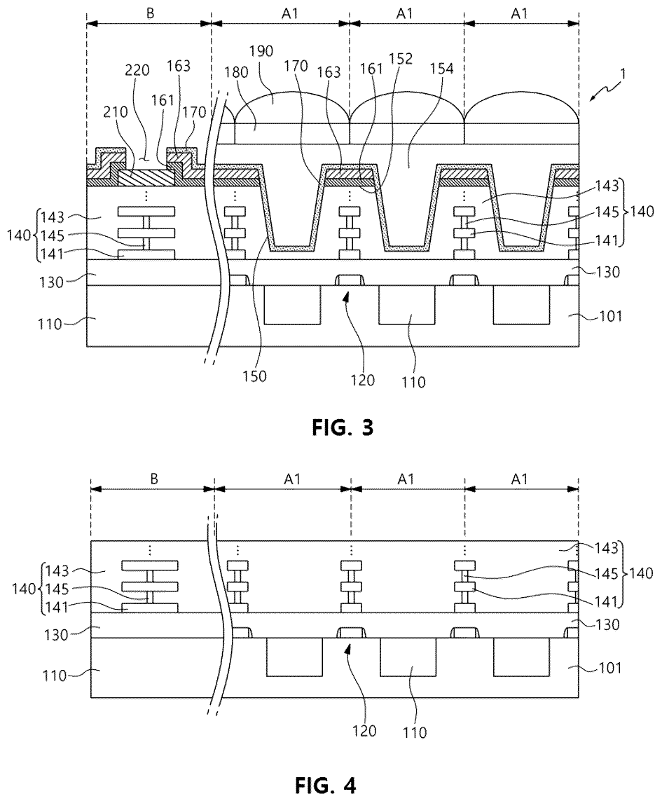

FIG. 3 is a cross-sectional view illustrating the image sensor 1 according to the embodiment of the present disclosure.

Hereinbelow, the image sensor 1 according to embodiment(s) of the present disclosure will be described in detail with reference to the accompanying drawings.

Referring to FIG. 3, the present disclosure relates to the image sensor 1. More particularly, the present disclosure relates to the image sensor 1, including a passivation layer 163 on a boundary 152, but not in a light guide 150, and a separate liner 170 is in the light guide 150 to control the light receiving efficiency of the light guide 150 according to the thickness of the liner 170.

The structure of the image sensor 1 will be described in detail.

First, a substrate 101 may include, for example, an epitaxial substrate (e.g., a single-crystal silicon wafer with an epitaxial silicon layer thereon), a bulk substrate, or the like. A plurality of wells (not illustrated) may be in the substrate 101. In addition, a device isolation layer (not illustrated) may be in the substrate 101. The device isolation layer may be formed by, for example, a shallow trench isolation (STI) process and may serve to isolate adjacent unit pixels A1 (e.g., physically and/or electronically from each other).

A light receiving element 110 may be in the substrate 101. The light receiving element 110 may be in each of the unit pixels Al, and may generate electrical charges in response to incident light (e.g., photons absorbed by the light receiving element 110). The light receiving element 110 may be comprise any one of a variety of known or to-be-known elements, for example, a photodiode, a photogate, or a phototransistor, but the present disclosure is not limited thereto. The light receiving element 110 may not be in the surrounding region B. In addition, a floating diffusion region (not illustrated) may be in the substrate 101 to transfer or read out electrical charges from the light receiving element 110.

A gate region 120 comprising, for example, a transistor is on the substrate 101. The gate region 120 may be at a boundary between adjacent unit pixels A1. In addition, the gate region 120 may include a charge transfer device, a selection device, a drive device, a reset device, and the like. Although the connection is not illustrated, the gate region 120 may be connected to a metal wiring layer 141. A lower insulating layer 130 may be on the substrate 101 to cover the gate region 120. The lower insulating layer 130 may also cover the light receiving element 110. The lower insulating layer 130 may include or comprise, for example, a silicon oxide layer (e.g., silicon dioxide) and/or a silicon nitride layer.

A wiring region 140 may be on the lower insulating layer 130. The wiring region 140 may comprise a multi-layered wiring structure between adjacent light guides 150 (which will be described later) and/or at the boundary between the unit pixels A1. The wiring region 140 may include one or more metal wiring layers 141, an interlayer insulating layer 143, and one or more contacts 145. The wiring region 140 may be in both the pixel A and the surrounding region B.

The metal wiring layer 141 may comprise, for example, a layer comprising a single metal or an alloy (e.g., comprising two or more metals). The metal wiring layer 141 preferably includes, for example, aluminum (Al) or an aluminum alloy (e.g., with copper and/or silicon).

The interlayer insulating layer 143 may comprise an insulating material, for example, silicon dioxide. The interlayer insulating layer 143 may be repeatedly and/or alternatingly stacked with the metal wiring layer 141 so that the metal wiring layer 141 forms a multi-layered wiring structure. The metal wiring layer 141 forming one layer of the multi-layered wiring structure may be connected to another metal wiring layer 141 of the multi-layered wiring structure through a contact or plug 145. The contact or plug 145 may be in each interlayer insulating layer 143, formed by a damascene process. In order to electrically connect overlapping metal wiring layers 141, the contact or plug 145 may comprise a conductive material, for example, selected from the group consisting of polycrystalline silicon doped with impurity ions, a metal (e.g., tungsten or aluminum), and an alloy (e.g., comprising at least two types of metals).

The interlayer insulating layer 143 may comprise an oxide selected from the group consisting of a borophosphosilicate glass (BPSG), a phosphosilicate glass (PSG), a borosilicate glass (BSG), an undoped silicate glass (USG), a silicon oxide formed from tetraethyl orthosilicate (TEOS), a silicon dioxide formed from, e.g., silane gas using a high density plasmas (an HDP oxide), or a combination thereof (e.g., including at least two layers selected from the aforementioned group). Also, the interlayer insulating layer 143 may be planarized by chemical mechanical polishing (CMP) after deposition. Although in the drawings the metal wiring layer 141 is illustrated as including three layers, the present disclosure is not limited thereto. An etch stop layer (e.g., comprising silicon nitride; not illustrated) may be at the interface between the lower insulating layer 130 and the wiring region 140.

The light guide 150 may be on or over the light receiving element 110 to guide incident light toward the light receiving element 110. The light guide 150 may have a structure passing through or between the wiring region 140. That is, the light guide 150 may pass through part or all of the interlayer insulating layer 143 where there is no metal wiring layer 141. For example, the light guide 150 may be in each of the unit pixels A1, and may comprise a cavity in the interlayer insulating layer 143, extending to the lower insulating layer 130 or to a depth close to the lower insulating layer 130. The light guide 150 may have inclined sidewalls and may decrease in lateral width as a function of depth into the interlayer insulating layer 143, but the present disclosure is not limited thereto.

The light guide 150 may facilitate incident light to more easily reach the light receiving element 110. In the absence of the light guide 150, incident light may be reflected or refracted due to interfaces between adjacent interlayer insulating layers 143 and/or the interface between the lowermost interlayer insulating layer 143 and the lower insulating layer 130. That is, the light guide 150 may increase the light received by the light receiving element 110. To this end, the light guide 150 may be over the light receiving element 110. The light guide 150 may therefore comprise a light-transmitting or transparent material. For example, an insulating layer 154 comprising a dielectric transparent to a wavelength or wavelength band of light to be received and/or detected by the light receiving element 110, or capable of guiding light, may be in the light guide 150. The insulating layer 154 may be in the cavity of the light guide 150 and on or over the passivation layer 163 in, on or over the wiring region 140.

The boundary 152 may be between adjacent light guides 150. The boundary 152 may also be a boundary between the unit pixels A1. The boundary 152 may preferably be in a part of the interlayer insulating layer 143 having a substantially flat upper surface and may be substantially orthogonal to the substantially flat upper surface of the interlayer insulating layer 143 (e.g., in or above the wiring region 140), but the present disclosure is not limited thereto. With this structure, the light guide 150 and the boundary 152 may alternate in the lateral direction (e.g., as shown in FIG. 3). In addition, the light guide 150 and the boundary 152 may be in the pixel region A, and the substantially flat uppermost surface of the interlayer insulating layer 143 may extend throughout the surrounding region B.

In the pixel region A, an upper insulating layer 161 may be on or at each boundary 152 and/or on or above the wiring region 140. The upper insulating layer 161 may be on or over the wiring region 140, but not to extend to the light guide 150, and may comprise, for example, a silicon dioxide layer. The upper insulating layer 161 may also be on the interlayer insulating layer 143 and a pad (e.g., a conductive bonding pad) 210 in the surrounding region B. For example, the upper insulating layer 161 may be on the interlayer insulating layer 143 and may cover lateral sides of the pad 210 in the surrounding region B.

In addition, in the pixel A, the passivation layer 163 may be on the upper insulating layer 161. The passivation layer 163 may comprise, for example, a silicon nitride layer formed by plasma-enhanced chemical vapor deposition (PECVD). After the passivation layer 163 is formed, the passivation layer 163 may be annealed to harden it. The passivation layer 163 may be on the upper insulating layer 161, but not in or over the light guide 150. In the surrounding region B, the passivation layer 163 may be on the upper insulating layer 161.

In the pixel A, the liner 170 may be in the light guide 150. The liner 170 may include, for example, a silicon nitride layer. The liner 170 may extend continuously in the light guide 150 and may be on the passivation layer 163 on the boundary 152. That is, the liner 170 may be formed between the light guide 150 and the insulating layer 154 and may be formed on the passivation layer 163 at or over the boundary 152. Therefore, the liner 170 may be in direct contact with the lower insulating layer 130 or the interlayer insulating layer 143 in the light guide 150. In addition, a structure comprising the upper insulating layer 161, the passivation layer 163, and the liner 170 stacked in three layers may be on the boundary 152.

In addition, in the surrounding region B, the liner 170 may be on the passivation layer 163. Therefore, the surrounding region B may have a three-layer structure comprising the upper insulating layer 161, the passivation layer 163, and the liner 170. In addition, the liner 170 may have a higher refractive index than the passivation layer 163 and the insulating layer 154, which will be described later, and the passivation layer 163 preferably has a higher refractive index than the insulating layer 154.

Hereinbelow, the structure of the image sensor 1 according to embodiment(s) of the present disclosure will be described in detail, along with a schematic structure of a conventional image sensor 9 and its problems.

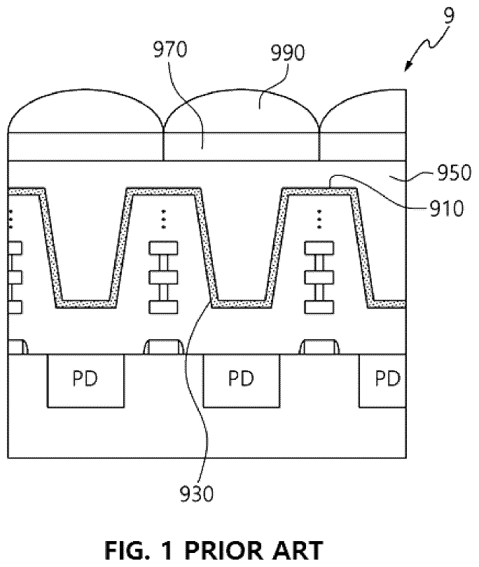

Referring to FIG. 1, in the conventional image sensor 9, a continuous passivation layer 910 is formed as a liner in a light guide 930 and a boundary between adjacent light guides 930. As such, the passivation layer 910 is both in a unit pixel and at a boundary between adjacent unit pixels. In addition, an insulating layer 950 is on the passivation layer 910 and in the light guide 930, a color filter 970 is on the insulating layer 950, and a microlens 990 is on the color filter 970. Thus, incident light may pass through the microlens 990 and the color filter 970 and be transferred to a light receiving element PD through the light guide 930.

In general, since the thickness of the passivation layer 910 is preset, it cannot be changed in order to stabilize device characteristics or secure reliability. For example, when the thickness of the passivation layer 910 is set to 1500 Å to 3000 Å, it is not easy to change the thickness of the passivation layer 910 to one outside this range. Therefore, it is also not easy to control the efficiency of the image sensor 9 for receiving incident light according to or as a function of the thickness of the passivation layer 910.

Meanwhile, referring to FIG. 3, the image sensor 1 according to the present disclosure includes the light guide 150 and the liner 170 in the light guide 150 and on the passivation layer 163. An upper insulating layer 161 on an interlayer insulating layer 143, and a passivation layer 163 on the upper insulating layer 161, is at a boundary or in a boundary region between adjacent light guides 150. With this structure, the liner 170 is in the light guide 150 instead of the passivation layer 163, and the thickness of the liner 170 can be more easily controlled. For example, the liner 170 can have a controllable and reproducible a thickness of 50 Å to 3000 Å. Therefore, it is possible to control the efficiency of the light receiving element 110 for receiving incident light through the light guide 150.

Continuing the description, in the pixel A, a color filter 180 may be on the insulating layer 154. The color filter 180 removes all but one of a plurality of colors (e.g., red, green, or blue, depending on the pixel and/or the colors of the adjacent pixels) from the incident light entering through a lens 190, which will be described later. The color selected may enter the light receiving element 110 of a corresponding unit pixel A1.

In addition, the lens 190 may be formed on the color filter 180. The lens 190 may be one of a plurality of microlenses that focus incident light onto the light receiving element 110 in a corresponding unit pixel A1. A planarization layer (not illustrated) may be between the insulating layer 154 and the color filter 180 and/or between the color filter 180 and the lens 190.

In the surrounding region B, a conductive pad 210 may be on the interlayer insulating layer 143. The pad 210 may be electrically connected to the metal wiring layer 141 therebelow. In addition, the pad 210 may be surrounded by and/or exposed through the upper insulating layer 161, the passivation layer 163, and the liner 170 (e.g., on lateral sides thereof and a part of an upper surface thereof), and an opening 220 may be in the upper insulating layer 161, the passivation layer 163, and the liner 170 exposing the uppermost surface of the pad 210. That is, the opening 220 may be formed by etching the upper insulating layer 161, the passivation layer 163, and the liner 170 over the pad 210. As a result, the pad 210 may be exposed. As illustrated, the width of the opening 220 may be substantially uniform or tapered, but the present disclosure is not limited thereto.

FIGS. 4 to 11 are cross-sectional views illustrating structures formed during a method of manufacturing an image sensor according to one or more embodiments of the present disclosure.

Hereinbelow, the method of manufacturing the image sensor according to embodiment(s) of the present disclosure will be described in detail with reference to the accompanying drawings.

First, referring to FIG. 4, a light receiving element 110 may be formed in each unit pixel A1 and in a substrate 101. The light receiving element 110 may comprise, for example, a photodiode. After that, a gate region 120 and a lower insulating layer 130 may be conventionally formed on the substrate 101. A wiring region 140 may then be formed on the lower insulating layer 130. Here, the metal wiring layers 141 in the wiring region 140 may include a metal wiring that carries driving signals for the image sensor and a metal wiring that carries driving signals for a logic circuit. The wiring region 140 may generally comprise two to five metal wiring layers 141. The metal wiring layers 141 may be formed, for example, by blanket-depositing (e.g., sputtering) the metal wiring layer 141 on an interlayer insulating layer 143, and then repeating, for example, photolithographic patterning and etching the blanket-deposited metal wiring layer, followed by dielectric (e.g., USG) deposition, planarization, silicon nitride layer deposition, annealing, and in all metal wiring layers 141 except the uppermost one, photolithographic patterning and etching the silicon nitride and USG layers to form contact holes, then conventionally filling the contact holes with contacts, to form a multi-layered metal wiring.

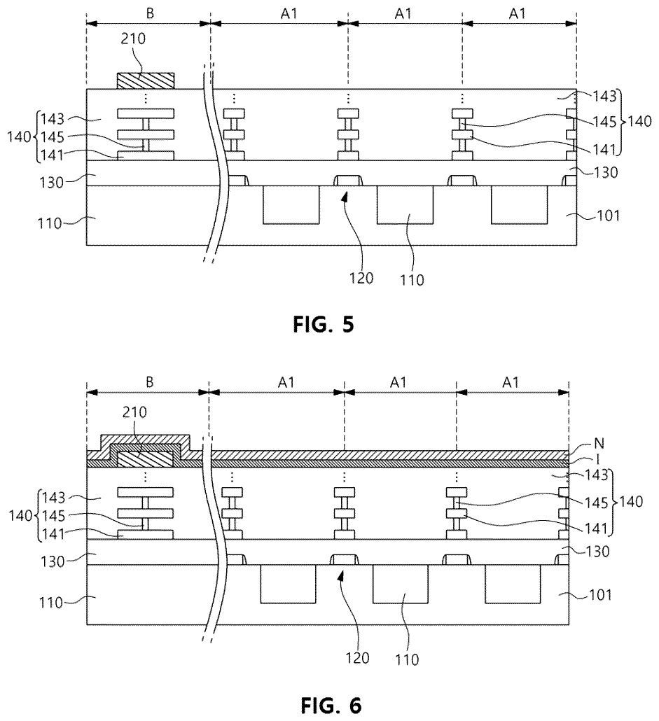

Then, referring to FIG. 5, a pad 210 may be conventionally formed on the interlayer insulating layer 143 in the surrounding region B, and a detailed description thereof will be omitted.

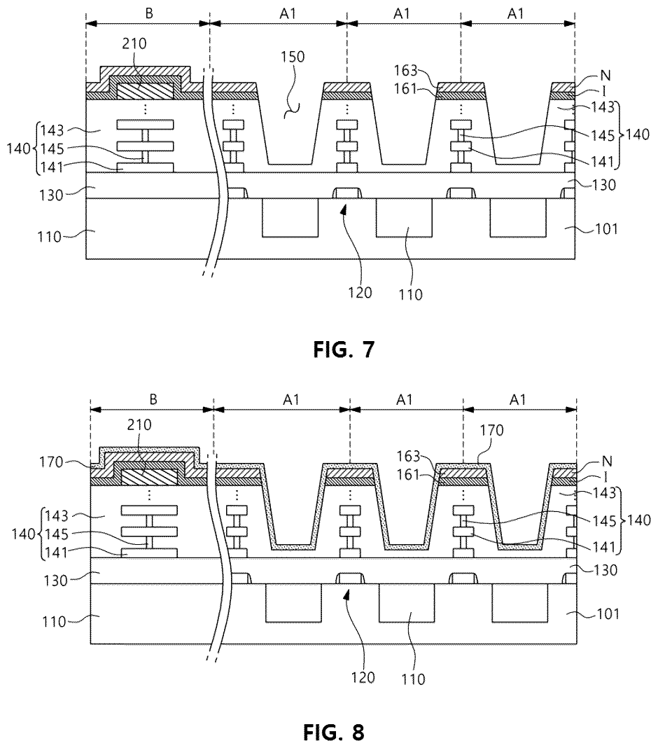

Thereafter, each light guide 150 and a boundary 152 between adjacent light guides 150 may be formed or defined in the pixel region A. This will be exemplarily described. First, referring to FIG. 6, an insulating layer I and a nitride layer N may be sequentially formed (e.g., by blanket deposition) on the interlayer insulating layer 143 in the pixel region A and the surrounding region B. In the surrounding region B, the insulating layer I and the nitride layer N may cover the pad 210. The insulating layer I may be or comprise, for example, a silicon dioxide layer, and the nitride layer N may be or comprise, for example, a silicon nitride layer. Then, referring to FIG. 7, each light guide 150 may be formed or defined by etching the nitride layer N, the insulating layer I and the interlayer insulating layer 143 using a photolithographically-patterned mask (not illustrated). Both the insulating layer I and the nitride layer N may be removed from the light guide 150, and the insulating layer I and the nitride layer N may remain on the interlayer insulating layer 143 on or at the boundary 152. The insulating layer I on or at the boundary 152 may become an upper insulating layer 161, and the nitride layer N may become a passivation layer 163.

Then, referring to FIG. 8, a liner 170 may be conformally deposited in the light guide 150 and the boundary 152 in the pixel region A and on the passivation layer 163 in the surrounding region B. As described above, the liner 170 may be or comprise, for example, a silicon nitride layer. By this process, the substantially conformal liner 170 may be on or in contact the lower insulating layer 130 or the interlayer insulating layer 143 in the light guide 150, and on the passivation layer 162 on the boundary 152.

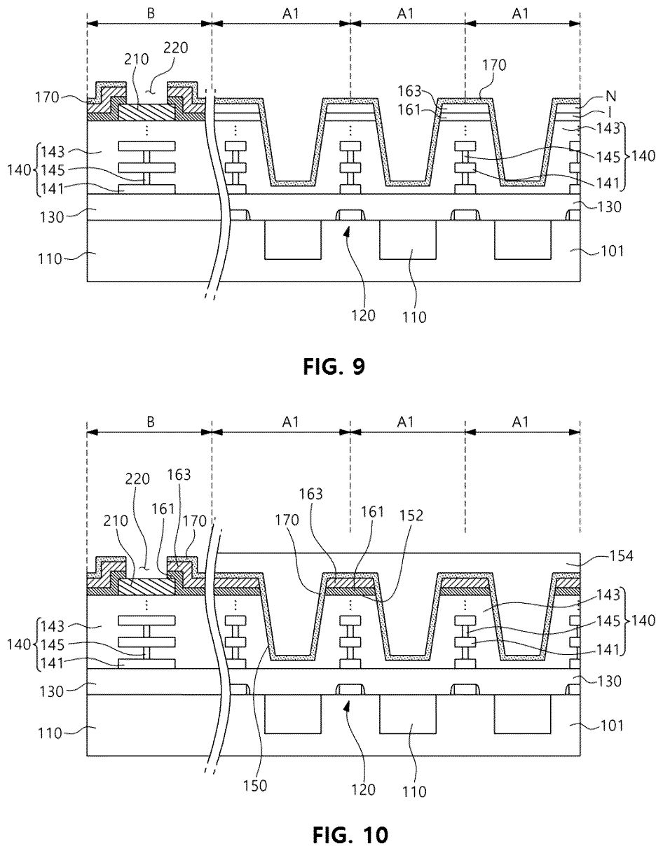

Then, referring to FIG. 9, an opening 220 may be formed in the surrounding region B. The opening 220 may be formed by etching the upper insulating layer 161, the passivation layer 163, and the liner 170 on the pad 210 in the surrounding region B using a photolithographically-patterned mask (not illustrated).

Then, referring to FIG. 10, an insulating layer 154 may be formed on the liner 170 in the pixel A, for example, by blanket deposition (e.g., spin-coating) and conventional selective removal from the surrounding region B. The insulating layer 154 may be in the cavity in the light guide 150. The insulating layer 154 may be or comprise, for example, an organic polymer, for example, a fluorine-based polymer having a ring structure, a polysiloxane resin, a polysiloxane resin and titanium oxide, or a polymer comprising poly(methyl methacrylate) (PMMA), but the present disclosure is not limited thereto. The insulating layer 154 may be formed on the liner 170 on or at the boundary 152.

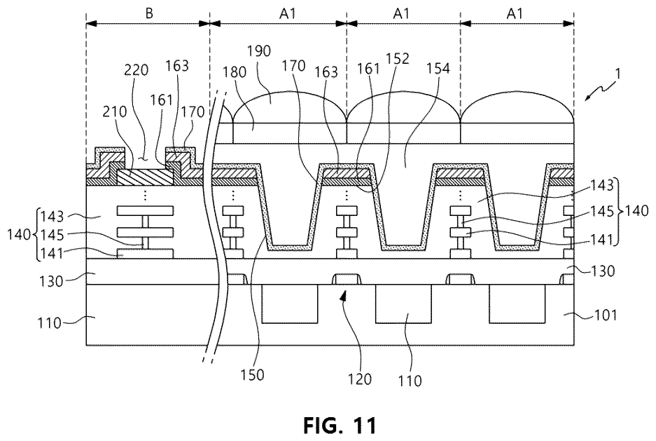

Then, referring to FIG. 11, in the pixel A, a color filter 180 may be conventionally formed on the insulating layer 154, and a lens 190 may be conventionally formed on the color filter 180. As described above, a planarization layer (not illustrated) may be formed on the insulating layer 154 before forming the color filter 180, and/or on the color filter 180 before forming the lens 190. In addition, after the lens 190 is formed, a separate process for removing residual materials from the uppermost surface of the device 1 may be performed.

The foregoing detailed description may be merely an example of the present disclosure. Also, the inventive concept is explained by describing the preferred embodiments and will be used through various combinations, modifications, and environments. That is, the inventive concept may be amended or modified without departing from the scope of the technical idea and/or knowledge in the art. The foregoing embodiments are for illustrating various modes for implementing the technical idea(s) of the present disclosure, and various modifications may be made therein according to specific applications and/or fields of use of the present disclosure. Therefore, the foregoing detailed description of the present disclosure is not intended to limit the inventive concept to the disclosed embodiments.

What is claimed is:

1. An image sensor comprising:
a substrate having a plurality of light receiving elements therein;
a gate region on the substrate;
a lower insulating layer covering the gate region;
a wiring region on the lower insulating layer, the wiring region comprising a multi-layered wiring structure and an interlayer insulating layer covering the metal wiring layer;
a light guide comprising a cavity in the interlayer insulating layer above each of the light receiving elements;
a boundary between adjacent light guides in the wiring region;
an upper insulating layer on or at the boundary;
a passivation layer on the upper insulating layer, and
a liner in the light guide and on the passivation layer.

2. The image sensor of claim 1, wherein the liner is in direct contact with the interlayer insulating layer in the light guide.

3. The image sensor of claim 1, wherein the liner covers sidewalls of the upper insulating layer and the passivation layer near the boundary.

4. The image sensor of claim 1, wherein the passivation layer is spaced apart from an adjacent passivation layer on or at an adjacent boundary.

5. The image sensor of claim 1, further comprising:
an insulating layer on the liner;
a color filter on the insulating layer; and
a lens on the color filter.

6. The image sensor of claim 5, wherein the liner has a higher refractive index than the insulating layer.

7. The image sensor of claim 6, wherein the liner has a higher refractive index than the passivation layer.

8. An image sensor comprising:
a substrate having a plurality of light receiving elements therein, each of the light receiving elements being in a corresponding pixel;
a lower insulating layer on the substrate;
a wiring region on the lower insulating layer, the wiring region comprising a multi-layered wiring structure and an interlayer insulating layer covering the metal wiring layer, a light guide comprising a cavity in the interlayer insulating layer above each of the light receiving elements;
a boundary between adjacent light guides in adjacent pixels;
a pad on the interlayer insulating layer in a surrounding region;
an upper insulating layer on or at the boundary and sidewalls of the pad in the surrounding region;
a passivation layer on the upper insulating layer,
a liner on the passivation layer and in contact with the interlayer insulating layer or the lower insulating layer in the light guide, and
an opening on or over the pad.

9. The image sensor of claim 8, wherein the liner has a thickness in a range of 50 Å to 3000 Å.

10. The image sensor of claim 8, wherein the light guide decreases in width as a function of depth in the cavity.

11. The image sensor of claim 8, wherein the liner is on the passivation layer in the pixel and the surrounding region.

12. A method of manufacturing an image sensor, the method comprising:
forming a light receiving element in a substrate;
forming a gate region on the substrate;
forming a lower insulating layer covering the gate region;
repeatedly forming a metal wiring layer and an interlayer insulating layer on the lower insulating layer,
sequentially forming an insulating layer and a nitride layer on an uppermost interlayer insulating layer,
forming an upper insulating layer, a passivation layer, and a light guide by etching the insulating layer, the nitride layer, and the interlayer insulating layer between adjacent boundaries of a unit pixel;
forming a liner in the light guide and on the passivation layer on or at the boundary; and
forming another insulating layer on the liner and filling the cavity.

13. The method of claim 12, wherein the liner is in direct contact with the lower insulating layer or the interlayer insulating layer in the light guide.

14. The method of claim 13, wherein the upper insulating layer, the passivation layer, and the liner are sequentially stacked on or at the boundary.

15. The method of claim 14, wherein the passivation layer has a higher refractive index than the upper insulating layer.

16. A method of manufacturing an image sensor, the method comprising:
forming a light receiving element in a substrate in a pixel;
forming a lower insulating layer on the substrate;
repeatedly forming a metal wiring layer and an interlayer insulating layer on the lower insulating layer in the pixel and a surrounding region;
forming a pad on an uppermost interlayer insulating layer in the surrounding region;
sequentially forming an insulating layer and a nitride layer on an uppermost interlayer insulating layer in the pixel and the surrounding region covering the pad;
forming a light guide by etching the insulating layer, the nitride layer, and the interlayer insulating layer in the pixel;
forming a liner in the light guide and in the surrounding region to cover the insulating layer and the nitride layer, and
forming an opening by sequentially etching the liner, the nitride layer, and the insulating layer on the pad.

17. The method of claim 16, wherein the liner is in contact with the lower insulating layer.
